(19) United States
(12) Patent Application Publication
(10) Pub. No.: US 2023/0029946 A1
(43) Pub. Date: Feb. 2, 2023

(54) EXTREMELY HIGH FREQUENCY ELECTROMAGNETIC WAVE TRANSMIT/RECEIVE DEVICE

(71) Applicants: STMicroelectronics SA, Montrouge (FR); STMicroelectronics (Grenoble 2) SAS, Grenoble (FR)

(72) Inventors: Victor FIORESE, Crolles (FR); Jean-Francois CAILLET, Sassenage (FR); Frederic GIANESELLO, Saint Jeoire Prieuré (FR); Fanny LAPORTE, Sassenage (FR)

(73) Assignees: STMicroelectronics SA, Montrouge (FR); STMicroelectronics (Grenoble 2) SAS, Grenoble (FR)

(21) Appl. No.: 17/871,452

(22) Filed: Jul. 22, 2022

(30) Foreign Application Priority Data
Aug. 2, 2021 (FR) 2108397

(51) Int. Cl. H01L 23/055; H01L 23/498; H01L 23/66; H01L 21/52

(52) U.S. Cl. CPC H01L 23/055; H01L 23/49822; H01L 23/66; H01L 21/52; H01L 2223/6627

(57) ABSTRACT

The present description concerns an electromagnetic wave transmit/receive device comprising a multilayer organic substrate, an integrated circuit chip, flip-chip assembled on the multilayer organic substrate, a package comprising a first cavity, containing the multilayer organic substrate and the integrated circuit chip, and communicating over a channel with a second cavity forming a waveguide for electromagnetic waves.

### BACKGROUND

### Technical Field

The present disclosure generally relates to extremely high frequency electromagnetic wave transmit/receive devices.

### Description of the Related Art

An extremely high frequency electromagnetic wave transmit/receive device may comprise an integrated circuit chip bonded to a support comprising an extremely high frequency electromagnetic wave transmit/receive antenna, the integrated circuit chip and the support being placed in a package containing a guide of extremely high frequency electromagnetic waves from/to the antenna.

It is desirable for losses during the transmission of the extremely high frequency electromagnetic waves between the antenna and the waveguide to be as small as possible. It is further desirable for the manufacturing cost of the device to be as low as possible.

### BRIEF SUMMARY

An object of an embodiment is to provide an extremely high frequency wave transmit/receive device overcoming all or part of the disadvantages of existing devices.

According to an object of an embodiment, losses during the transmission of the extremely high frequency electromagnetic waves between the antenna and the waveguide of the device are decreased.

According to an object of an embodiment, the manufacturing cost of the device is decreased.

An embodiment provides an electromagnetic wave transmit/receive device comprising a multilayer organic substrate, an integrated circuit chip, flip-chip assembled on the multilayer organic substrate, a package comprising a first cavity, containing the multilayer organic substrate and the integrated circuit chip, and communicating over a channel with a second cavity forming a waveguide for electromagnetic waves.

According to an embodiment, the first cavity comprises a first recess opposite the integrated circuit chip.

According to an embodiment, the first cavity comprises a second recess coupling the channel to the first recess.

According to an embodiment, the multilayer organic substrate comprises a main portion in the first cavity and a protrusion extending from the main portion into the channel and penetrating into the second cavity.

According to an embodiment, the multilayer organic substrate comprises an antenna for transmitting/receiving the electromagnetic waves on the protrusion in the second cavity.

According to an embodiment, the multilayer organic substrate comprises an electrically-insulating support made of an organic material.

According to an embodiment, the support comprises first and second opposite surfaces, electrically-conductive tracks extending over the first surface, and an electrically-insulating layer covering the electrically-conductive tracks.

According to an embodiment, the protrusion of the multilayer organic substrate does not comprise the support in the second cavity.

According to an embodiment, the protrusion of the multilayer organic substrate does not comprise the support in the channel.

According to an embodiment, the multilayer organic substrate further comprises a coating comprising a graphene layer covering the electrically-insulating layer.

According to an embodiment, the multilayer organic substrate comprises an electrically-conductive line coupling the antenna to the integrated circuit chip, where the coating does not cover the electrically-conductive line in the first cavity.

According to an embodiment, the electromagnetic waves are in a frequency band from 30 GHz to 260 GHz.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is a partial simplified perspective view of an embodiment of an extremely high frequency electromagnetic wave transmit/receive device;

FIG. 2 is a partial simplified cutaway view of the device of FIG. 1;

FIG. 3 is a partial simplified cutaway view of the device of FIG. 1 illustrating an embodiment of the multilayer organic substrate of the device;

FIG. 4 is a partial simplified cross-section view of another embodiment of the multilayer organic substrate;

FIG. 5 is a partial simplified perspective view of an embodiment of the multilayer organic substrate;

FIG. 6 is a partial simplified top view of the multilayer organic substrate of FIG. 5;

FIG. 7 is a partial simplified cutaway top view of the package of the device of FIGS. 1 and 2;

FIG. 8 is a partial simplified cutaway side view of the package of the device of FIGS. 1 and 2;

FIG. 9 is a partial simplified enlarged cutaway side view of the device of FIGS. 1 and 2;

FIG. 10 is a partial simplified enlarged cutaway top view of the device of FIGS. 1 and 2;

FIG. 11 is a partial simplified cross-section view of an embodiment of the multilayer organic substrate in a cross-section plane of FIG. 9;

FIG. 12 is a partial simplified cross-section view of an embodiment of the multilayer organic substrate in another cross-section plane of FIG. 9;

FIG. 13 is a partial simplified cross-section view of an embodiment of the multilayer organic substrate in another cross-section plane of FIG. 9;

FIG. 14 is a partial simplified cutaway top view of a device used for simulations;

FIG. 15 is a partial simplified cutaway top view of the optoelectronic device of FIG. 14;

FIG. 16 is a perspective view of the multilayer organic substrate of the device of FIG. 14;

FIG. 17 is a perspective view illustrating the arrangement of the multilayer organic substrate of FIG. 16 in the package of the device of FIGS. 14 and 15; and

FIG. 18 shows a curve of the variation of the insertion losses of the device of FIG. 14 according to frequency.

### DETAILED DESCRIPTION

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the integrated circuit chip and multilayer organic substrate manufacturing steps are not detailed, the described embodiments being compatible with usual steps.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, it is here considered that the terms “insulating” and “conductive” respectively signify “electrically insulating” and “electrically conductive”.

In the following description, when reference is made to terms qualifying absolute positions, such as terms “front,” “rear,” “top,” “bottom.” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings or to a display screen in a normal position of use.

Unless specified otherwise, the expressions “around,” “approximately,” “substantially” and “in the order of” signify within 10%, and preferably within 5%. Unless specified otherwise, ordinal numerals such as “first,” “second,” etc., are only used to distinguish elements from one another. In particular, these adjectives do not limit the described embodiments to a specific order of these elements.

The present application aims at applications of emission, reception, and/or transmission of electromagnetic waves, in particular electromagnetic waves in a frequency band extending from 30 GHz to 300 GHz (extremely high frequency band or EHF band), preferably from 140 GHz to 220 GHz (G band), such electromagnetic waves being called EHF waves hereafter. For space applications, the frequency ranges of interest may more particularly range from 50 GHz to 260 GHz.

FIGS. 1, 2, and 3 respectively are a perspective view with transparency, a cutaway top view, and a cutaway lateral view, partial and simplified, of an embodiment of an EHF wave transceiver device 100. In FIG. 1, the lines visible for an observer from the outside of device 100 have been shown in thick lines and the lines which are not visible for an observer from the outside of device 100 have been shown in thin lines.

Device 100 comprises:

a package 200 delimiting at least a first cavity 202 and a second cavity 204, the first cavity 202 communicating with the second cavity 204 over a channel 206, the second cavity 204 emerging at one end 207 towards the outside of package 200;

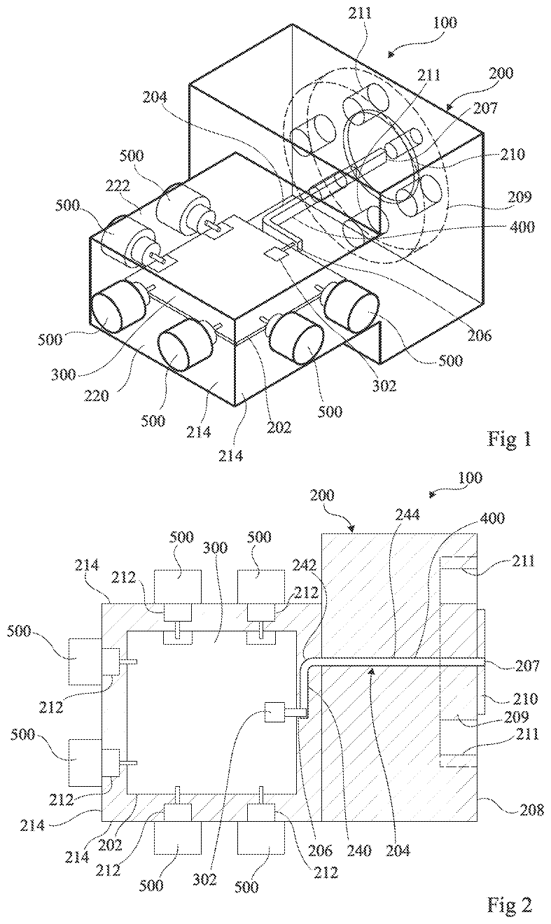

a multilayer organic substrate 300, having an integrated circuit chip 302 bonded thereto, multilayer organic substrate 300 and integrated circuit chip 302 being housed in the first cavity 202, the cross-section plane of FIG. 2 being located substantially at the level of the upper surface of multilayer organic substrate 300;

an EHF waveguide 400 at least partly formed by the second cavity 204 of package 200 and communicating towards the outside of package 200; and

electric connectors 500 at least partly housed in package 200.

Package 200 comprises a surface 208 having the end 207 of the second cavity 204 emerging onto it. In the embodiment shown in FIGS. 1 and 2, surface 208 is substantially essentially orthogonal to the main surfaces of multilayer organic substrate 300. According to an embodiment, package 200 comprises, on surface 208, a portion 209 forming a waveguide connector, schematically shown in FIGS. 1 and 2. The end 207 of second cavity 204 emerges onto surface 208 at the level of connector 209. Surface 208 may be planar or exhibit a bump 210 having the end 207 of second cavity 204 emerging onto it. In operation, another waveguide, not shown in the drawings, is intended to be connected to package 200 at the level of connector 209. For this purpose, connector 209 may comprise openings 211 for screws and alignment pins of the waveguide.

Package 200 comprises at least one housing 212 intended to receive the electric connectors 500 connected to multilayer organic substrate 300. Housing 212 is open on at least one surface 214 of package 200. Housing 212 has first cavity 202 communicate with the surface 214 of package 200. In the embodiment shown in FIGS. 1 and 2, housing 212 is separate for each electric connector 500. Each housing 212 emerges at one end onto surface 214 and emerges, at the opposite end, into first cavity 202. As an example, in the embodiment shown in FIGS. 1 and 2, six electric connector 500 are in contact with multilayer organic substrate 300 via six housings 212. The six housings 212 emerge, two by two, onto three distinct lateral surfaces 214 of package 200. Two surfaces 214 are orthogonal to surface 208 and one surface 214 is opposite to surface 208. As a variant, housing 212 may comprise a common portion for a plurality of electric connectors 500, the common portion being continued, for each electric connector 500, by an end portion coupling the common portion to the first cavity.

Package 200 may comprise a lower portion 220 bonded to an upper portion 222. Multilayer organic substrate 300 may then be located between lower portion 220 and upper portion 222. In the embodiment illustrated in FIGS. 1, 2, and 3, an edge 224 of lower portion 220 directly bears against an edge 226 of upper portion 222. First cavity 202 may then correspond to the interstice delimited between lower portion 220 and upper portion 222 when the edge 224 of the lower portion 220 directly bears against the edge 226 of upper portion 222. The edge 224 of lower portion 220 may be in mechanical contact with the edge 226 of upper portion 222 all along the periphery of first cavity 202, except for the channel 206 coupling first cavity 202 to second cavity 204. As a variant, multilayer organic substrate 300 may be sandwiched between lower portion 220 and upper portion 222, lower portion 220 directly bearing against multilayer organic substrate 300 and upper portion 222 directly bearing against multilayer organic substrate 300. First cavity 202 may then correspond to the interstice present between lower portion 220 and upper portion 222 when lower portion 220 directly bears against multilayer organic substrate 300 and upper portion 222 directly bears against multilayer organic substrate 300.

According to an embodiment, second cavity 204 comprises a first rectilinear portion 240, continued by an angled portion 242, itself possibly continued by a second rectilinear portion 244. Channel 206 emerges into the first rectilinear portion 240 of second cavity 204. In the embodiment of package 200 illustrated in FIGS. 1 and 2, second rectilinear portion 244 emerges onto the bump 210 present on surface 208.

Package 200 is at least partly made of an electrically-conductive material, for example, brass or aluminum. According to an embodiment, package 200 is entirely made of an electrically-conductive material. Package 200 may be formed by machining. As a variant, package 200 may be formed by 3D printing, also called additive printing. Integrated circuit chip 302 may be based on silicon, gallium arsenide, indium phosphide, silicon-germanium, or gallium nitride.

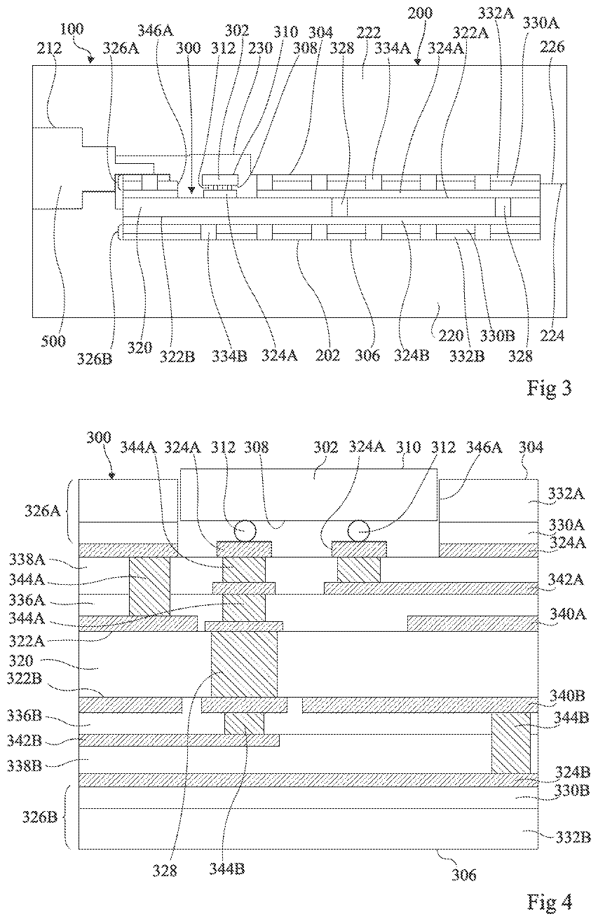

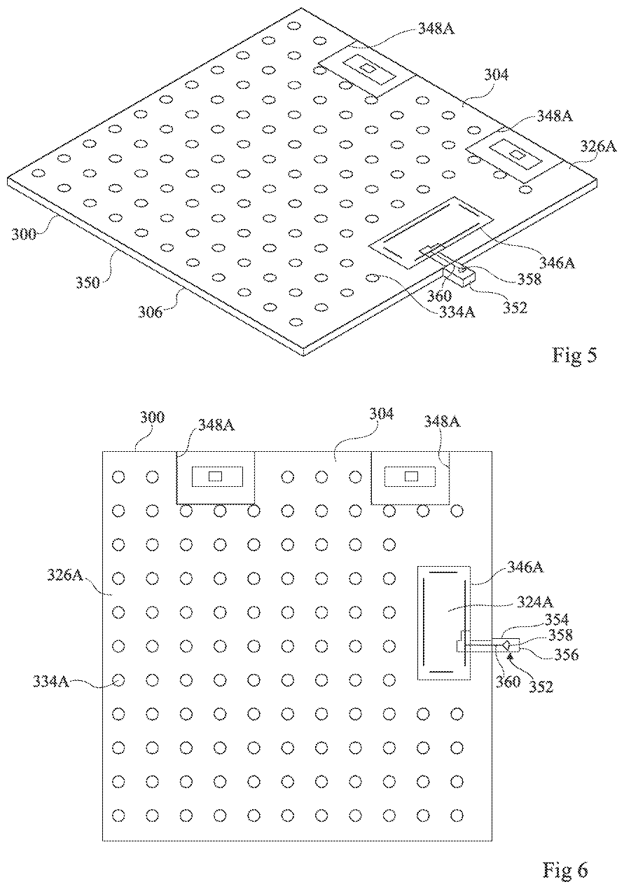

FIG. 3 further illustrates the structure of an embodiment of multilayer organic substrate 300 and of integrated circuit chip 302. FIG. 4 is a partial simplified cross-section view of another embodiment of multilayer organic substrate 300. FIGS. 5 and 6 respectively are a partial simplified perspective view and top view of an embodiment of multilayer organic substrate 300.

Multilayer organic substrate 300 comprises an upper surface 304 and a lower surface 306. Integrated circuit chip 302 comprises a front surface 308 and a rear surface 310. Integrated circuit chip 302 is bonded to the upper surface 304 of multilayer organic substrate 300 by a flip-chip bonding. The front surface 308 of integrated circuit chip 302 is located in front of the upper surface 304 of multilayer organic circuit 300 and is bonded to multilayer organic substrate 300 by connection elements 312, for example, solder balls or aluminum pads. The bonding between integrated circuit chip 302 and multilayer organic substrate 300 is called flip chip since, conversely to a wire bonding where the upper surface 304 of the multilayer organic substrate 300 and the front surface 308 of the integrated circuit chip 302 receiving the connection solders (or contacts) have to be in the same direction, that it, they are not opposite, for the “flip-chip” technique, the upper surface 304 of the multilayer organic substrate 300 and the front surface 308 of integrated circuit chip 302 have to be facing each other (that is, in an opposite direction). Integrated circuit chip 302 is thus effectively flipped with respect to the configuration where it would be bonded to multilayer organic substrate 300 by wire bonding.

For each of these embodiments illustrated in FIGS. 3 and 4, multilayer organic substrate 300 comprises an insulating support 320 having two opposite surfaces 322A, 322B, and for each surface 322A, 322B, conductive tracks 324A, 324B, or a conductive layer on surface 322A, 322B, a coating 326A, 326B covering conductive tracks 324A, 324B and support 320 between conductive tracks 324A, 324B, and conductive vias 328 coupling tracks 324A to conductive tracks 324B through insulating support 320. Integrated circuit chip 302 is located on the side of surface 322A of support 320. Each coating 326A, 326B may have a monolayer or multilayer structure. As an example, each coating 326A, 326B comprises a stack of two layers 330A, 330B and 332A, 332B, the layer 330A, 330B closest to insulating support 320 being an insulating layer. Multilayer organic substrate 300 may further comprise conductive vias 334A, 334B, only shown in FIG. 3, fully crossing coating 326A, 326B and connected to an end of conductive tracks 324A, 324B. In the embodiment of package 200 shown in FIGS. 1 and 2, an electric connector 500 may come into contact with one of conductive vias 334A, as shown in FIG. 3.

In the embodiment illustrated in FIG. 4, multilayer organic substrate 300 comprises, as an example, three metallization levels on each surface 322A, 322B of support 320. More precisely, the multilayer organic substrate 300 illustrated in FIG. 4 comprises all the elements of the multilayer organic substrate 300 shown in FIG. 3 and further comprises, on the side of each surface 322A, 322B, between conductive tracks 324A, 324B and surface 322A, 322B, a stack of two insulating layers 336A, 336B and 338A, 338B covering surface 322A, 322B, conductive tracks 340A, 340B, between insulating layer 336A, 336B and surface 222A, 222B, conductive tracks 342A, 342B, between insulating layer 336A, 336B and insulating layer 338A, 338B and conductive vias 344A, 344B connecting conductive tracks 324A, 324B to conductive tracks 340A, 340B, conductive tracks 340A, 340B to conductive tracks 342A, 342B and/or conductive tracks 324A, 324B to conductive tracks 342A, 342B.

Support 320 is a layer of an organic material, for example, a polymer, in particular an epoxy resin reinforced with fibers, particularly a fiberglass reinforced bismaleimide-triazide resin. The thickness of support 320 may vary from 60 μm to 100 μm, and is for example equal to approximately 80 μm. Each insulating layer 330A, 330B, 336A, 336B, 338A, 338B may be a polymer layer protecting the conductive tracks from oxidation. The maximum thickness of each insulating layer 336A, 336B 338A, 338B may vary from 20 μm to 60 μm and is for example equal to approximately 48 μm. The thickness of each insulating layer 330A, 330B may vary from 5 μm to 25 m, and is for example equal to approximately 15 m. Each conductive track 324A, 324B, 340A, 340B, 342A, 342B may be made of copper. The thickness of each conductive track 324A, 324B, 340A, 340B may vary from 10 μm to 25 μm, and is for example equal to approximately 18 μm. The thickness of each conductive track 342A, 342B may vary from 5 μm to 15 μm, and is for example equal to approximately 8 μm. Each conductive via 344A, 344B may be made of copper. The layer 332A, 332B of coating 326A, 326B is preferably made of an electrically-conductive material, for example, of graphene. The thickness of layer 332A, 332B may vary from 0.05 mm to 0.3 mm, and is for example equal to approximately 0.12 mm.

Advantageously, the manufacturing costs of multilayer organic substrate 300 are decreased with respect to the case where the support having the integrated circuit chip bonded thereto is made of quartz.

Coating 326A and possibly insulating layers 336A and 338A comprise a through opening 346A particularly at the location of integrated circuit chip 302 exposing conductive tracks 324A, 342A, or 340A. Coating 326A and possibly insulating layers 336A, 338A may comprise at least another through opening 348A exposing conductive tracks 324A, 342A, or 340A, for example, to allow the connection of an electric connector 500 to conductive tracks 324A, 342A, or 340A. In FIGS. 5 and 6, multilayer organic substrate 300 is shown with two through openings 348A in coating 326A and one opening 346A in coating 326A.

According to an embodiment, multilayer organic substrate 300 comprises a main portion 350, which occupies in the top view at least 90% of the total surface area of multilayer organic substrate 300, and at least one protrusion 352 which projects from an edge of main portion 350. Main portion 350 may have, in top view, a square or rectangular shape. Protrusion 352 may have, in top view, a rectangular shape. Protrusion 352 comprises an intermediate portion 354 which extends in channel 206 and an end portion 356 which extends in second cavity 204 when multilayer organic substrate 300 is placed in package 200. Multilayer organic substrate 300 comprises an EHF wave transceiver antenna 358, for example formed by a conductive track 324A, 340A, or 342A, in end portion 356. Antenna 358 is coupled to integrated circuit chip 302 by a conductive track 360, for example, rectilinear. According to an embodiment, coating 326A is not present on antenna 358 and conductive track 360.

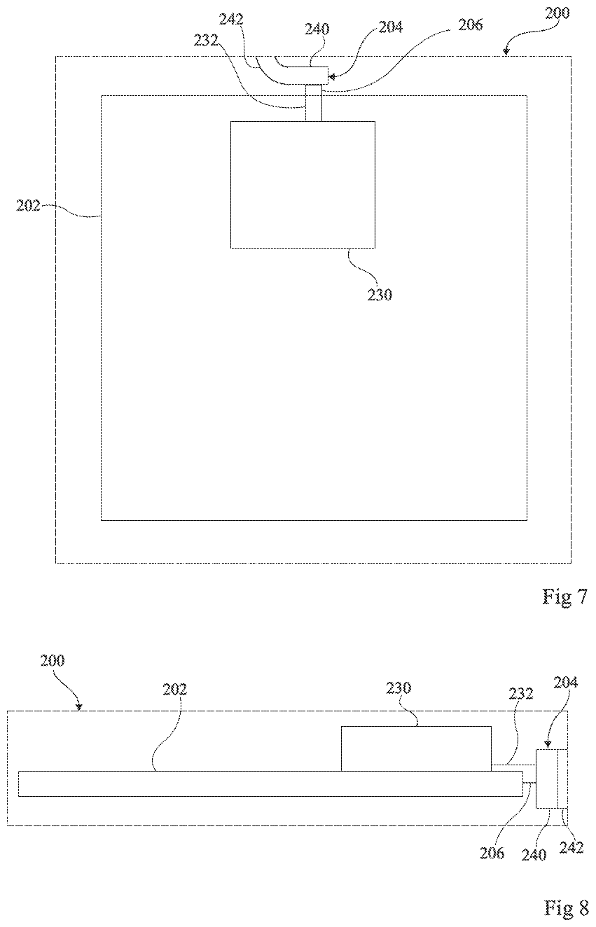

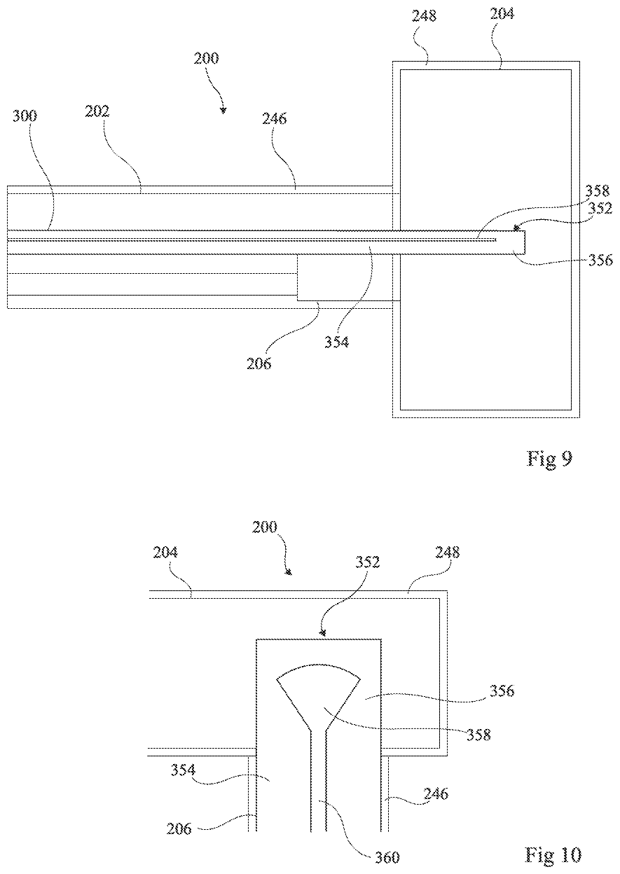

FIGS. 7 and 8 respectively are a cutaway top view and a cutaway side view, partial and simplified, of an embodiment of a portion of package 200. FIGS. 9 and 10 are enlarged views respectively of FIGS. 7 and 8, multilayer organic substrate 300 being further shown in these drawings. FIGS. 7 to 10 further illustrate a more detailed embodiment of first cavity 202.

According to an embodiment, first cavity 202 comprises a first recess 230, also shown in FIG. 3, having integrated circuit chip 302 housed therein. According to an embodiment, first cavity 202 comprises a second recess 232 coupling first recess 230 to channel 206. Second recess 232 may be absent.

The dimensions of channel 206, of first cavity 202, and of second cavity 204 particularly depend on the wavelength of the EHF waves to be transmitted by second cavity 204. According to an embodiment, the dimensions of first cavity 202 in top view substantially correspond to the dimensions, in top view, of the main portion 350 of multilayer organic substrate 300. According to an embodiment, first cavity 202 has, in top view, the shape of a square or of a rectangle, each side length of which may vary from 5 mm to 25 mm, for example, be equal to approximately 15 mm. According to an embodiment, the dimensions of the first recess 230 in top view substantially correspond to the dimensions, in top view, of integrated circuit chip 302. According to an embodiment, first recess 230 has, in top view, the shape of a square or of a rectangle, each side length of which may vary from 2 mm to 8 mm. The length of channel 206 between first cavity 202 and second cavity 204 may vary from 0.2 mm to 0.6 mm, and is for example equal to approximately 0.4 mm for the frequency range from 140 GHz to 220 Hz. The height of channel 206 may vary from 0.2 mm to 0.6 mm, and is for example equal to approximately 0.4 mm for the frequency range from 140 GHz to 220 Hz.

According to an embodiment, the cross-section area of second cavity 204 is constant all along first rectilinear portion 240, angled portion 242, and second rectilinear portion 244. Second cavity 204 may have a square or rectangular cross-section, each side length of which may vary from 0.5 mm to 1.5 mm, and for example corresponds to a rectangular cross-section having a small side length equal to approximately 0.8 mm and a large side length equal to approximately 1.3 mm. In FIGS. 9 and 10, a coating 246 covering the walls of first cavity 202 and of channel 206 and a coating 248 covering the wall of second cavity 204 have been shown. Coating 246 and/or coating 248 may be made of a tin and gold alloy. Coating 246 may be deposited on the walls of first cavity 202 and of channel 206 and/or coating 248 may be deposited on the walls of second cavity 204 to limit the oxidation, improve the surface state and the electric conductivity.

According to an embodiment, outside of the first and second recesses 230, 232, first cavity 202 has a height which is substantially constant and that may vary from 0.5 mm to 1 mm, and is for example equal to approximately 0.6 mm for the frequency range from 140 GHz to 220 Hz. The depth of first recess 230 may vary from 1 mm to 2 mm, and is for example equal to approximately 1.5 mm. The total height of first cavity 202 at the level of second recess 232 may vary from 0 mm to 0.3 mm. The fact for integrated circuit chip 302 to be bonded to multilayer organic substrate 300 according to a flip-chip bonding advantageously enables to decrease the depth of first recess 230 with respect to what would be necessary if integrated circuit chip 302 was bonded to multilayer organic substrate 300 by a wire bonding. An air film is advantageously provided, covering protrusion 352 in channel 206. The thickness of the air film covering protrusion 352 in channel 206 may vary from 200 μm to 400 μm, and is for example equal to 300 μm. In first cavity 202, an air film may be present between coating 226A and the upper portion of package 200.

FIG. 11 is a partial simplified cross-section view of an embodiment of multilayer organic substrate 300, having the multilayer structure illustrated in FIG. 4, in main portion 350 outside of first recess 230.

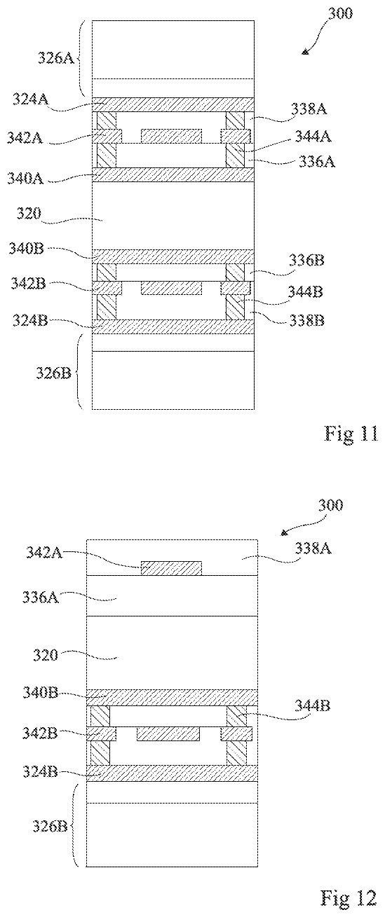

FIG. 12 is a partial simplified cross-section view of an embodiment of multilayer organic substrate 300, having the multilayer structure illustrated in FIG. 4, in first cavity 202 at the level of second recess 232. Coating 326A is not present.

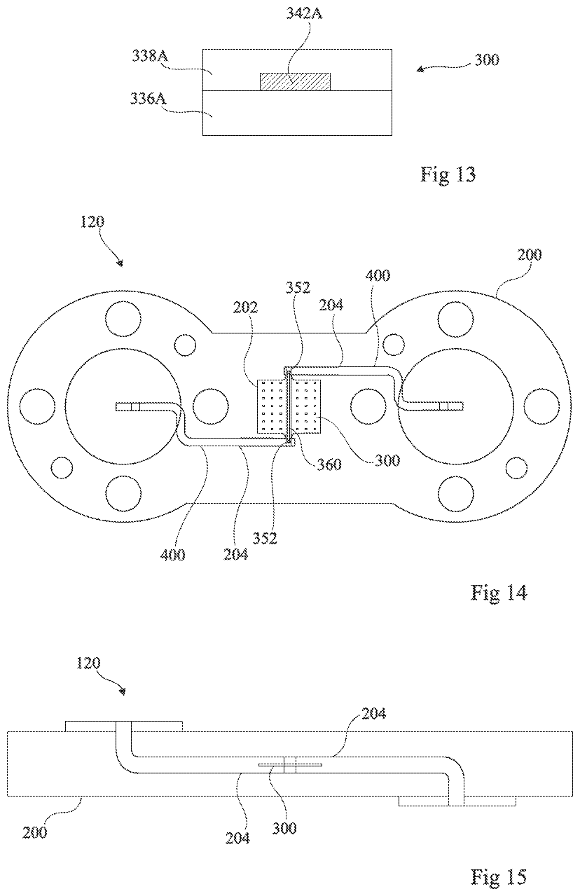

FIG. 13 is a partial simplified cross-section view of an embodiment of multilayer organic substrate 300 in protrusion 252, having the multilayer structure illustrated in FIG. 4, in channel 206 and second cavity 204. Coating 326A, support 320, insulating layers 336B, 338B, and coating 326B are not present.

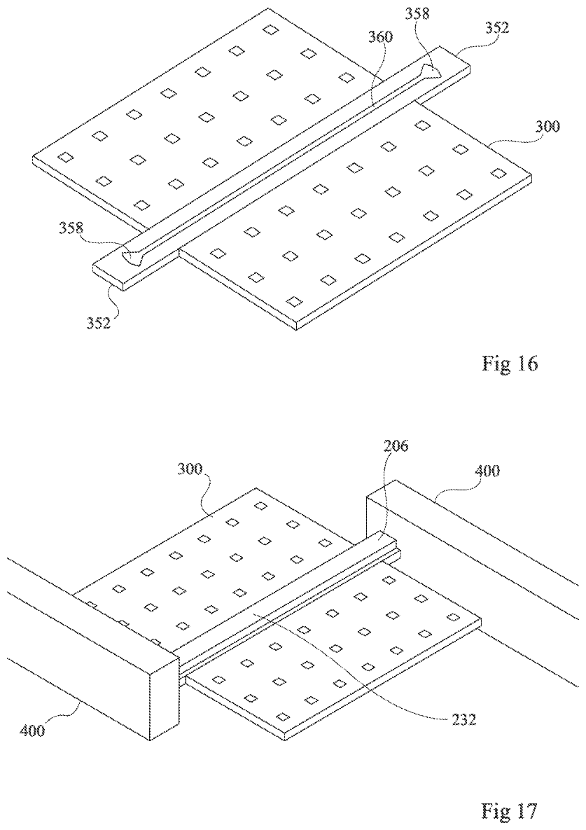

FIGS. 14 and 15 respectively are a cutaway top view and a cutaway side view, partial and simplified, of an embodiment of a device 120 of transmission of EHF waves used to perform simulations. FIG. 16 is a perspective view of an embodiment of a multilayer organic substrate 300 used to perform the simulations. FIG. 17 is a perspective view showing the multilayer organic substrate 300 of FIG. 16 assembled in the package 200 of the device 120 of FIGS. 14 and 15.

The simulations aim at determining the EHF wave transmission properties between multilayer organic substrate 300 and waveguide 400. For the simulations, integrated circuit chip 302 is not present. Package 200 has a symmetrical structure and comprises a first cavity 202 and two second cavities 204 forming two EHF waveguides 400.

Multilayer organic substrate 300 has a symmetrical shape and comprises two protrusions 352, each comprising an EHF wave transceiver antenna 358, the two antennas 358 being connected to each other via conductive track 360. As shown in FIG. 17, each antenna 358 is located in one of the second cavities 204 and the second recess covers conductive track 360. For the simulations, an electromagnetic wave is supplied at the end of one of waveguides 400 and the electromagnetic wave which is emitted at the end of the other waveguide 400 is detected.

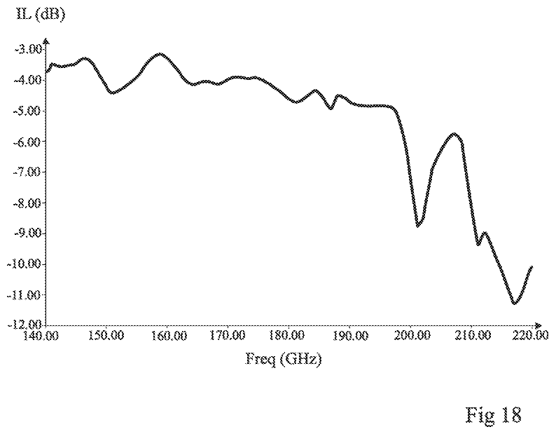

FIG. 18 shows a curve of variation of insertion losses IL, in dB, at the level of a link between a waveguide 400 and the multilayer organic substrate 300 of the device 120 of FIG. 14 according to frequency Freq. The insertion losses are compatible with an application in the space industry.

Various embodiments and variants have been described. Those skilled in the art will understand that certain features of these various embodiments and variants may be combined, and other variants will occur to those skilled in the art. Finally, the practical implementation of the described embodiments and variants is within the abilities of those skilled in the art based on the functional indications given hereabove.

An electromagnetic wave transmit/receive device (100) may be may be summarized as including a multilayer organic substrate (300), an integrated circuit chip (302), flip-chip assembled on the multilayer organic substrate, a package (200) comprising a first cavity (202), containing the multilayer organic substrate and the integrated circuit chip, and communicating over a channel (206) with a second cavity (204) forming a waveguide (400) for electromagnetic waves.

The first cavity (202) may include a first recess (230) opposite the integrated circuit chip (302).

The first cavity (202) may include a second recess (232) coupling the channel (206) to the first recess (230).

The multilayer organic substrate (300) may include a main portion (350) in the first cavity (202) and a protrusion (352) extending from the main portion into the channel (206) and penetrating into the second cavity (204).

The multilayer organic substrate (300) may include an electromagnetic wave transmit/receive antenna (258) on the protrusion (252) in the second cavity (204).

The organic multilayer substrate (300) may include an electrically-insulating support (320) made of an organic material.

The support (320) may include first and second opposite surfaces (322A, 322B), electrically-conductive tracks (324A, 340A, 342A) extending on the first surface, and an electrically-insulating layer (326A, 336A, 338A) covering the electrically-conductive tracks.

The protrusion (252) of the multilayer organic substrate (300) may not include the support (320) in the second cavity (204).

The protrusion (252) of the multilayer organic substrate (300) may not include the support (320) in the channel (206).

The multilayer organic substrate (300) may further include a coating (326A) including a graphene layer (332A) covering the electrically-insulating layer (338A).

The multilayer organic substrate (300) may include an electrically-conductive line (360) coupling the antenna (358) to the integrated circuit chip (302), where the coating (326A) does not cover the electrically-conductive line in the first cavity (202).

The electromagnetic waves may be in a frequency band from 30 GHz to 260 GHz. The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a multilayer organic substrate;
an integrated circuit chip, flip-chip assembled on the multilayer organic substrate; and
a package including a first cavity, containing the multilayer organic substrate and the integrated circuit chip, the first cavity configured to communicate over a channel with a second cavity, the second cavity forming a waveguide for electromagnetic waves, the package including:
an antenna in the substrate and coupled to the integrated circuit chip, the antenna extending in the first cavity and partially into the second cavity.

2. The device according to claim 1, wherein the first cavity includes a first recess, the integrated circuit chip being in the first recess.

3. The device according to claim 2, wherein the first cavity includes a second recess that is between the second cavity and the first recess.

4. The device according to claim 1, wherein the multilayer organic substrate includes a main portion in the first cavity and a protrusion extending from the main portion into the channel and penetrating into the second cavity.

5. The device according to claim 1, wherein an electrically-insulating support in the substrate includes first and second opposite surfaces, electrically-conductive tracks extending on the first surface, and an electrically-insulating layer covering the electrically-conductive tracks.

6. The device according to claim 5, wherein the multilayer organic substrate further includes a coating including a graphene layer covering the electrically-insulating layer.

7. The device according to claim 6, wherein the multilayer organic substrate includes the antenna on a protrusion in the second cavity, and wherein the multilayer organic substrate includes an electrically-conductive line coupling the antenna to the integrated circuit chip, where the coating does not cover the electrically-conductive line in the first cavity.

8. A device, comprising:
a package having a first surface opposite to a second surface;
a first cavity in the package;
a first plurality of conductive layers in the first cavity closer to the first surface than the second surface;
a first insulating layer in the first cavity, the first insulating layer being spaced from the first surface by the first plurality of conductive layers;
a second plurality of conductive layers in the first cavity closer to the second surface than the first surface;
a second cavity in the package, the second cavity being closer to the second surface than the first surface;
an integrated circuit chip on the first insulating layer;
a waveguide coupled to the integrated circuit and being at least partially in the second cavity; and
a plurality of electric connectors extending from a side of the package that is different from a side of the package from which the waveguide extends.

9. The device of claim 8 wherein the first plurality of conductive layers, the first insulating layer, and the second plurality of conductive layers are a substrate in the package.

10. The device of claim 9 wherein the plurality of electric connectors extends from the package into an external environment.

11. The device of claim 9 wherein the second cavity extends from the substrate to an edge of the package.

12. A method, comprising:
forming a first cavity in a package having a first surface opposite to a second surface;
forming a first plurality of conductive layers in the first cavity closer to the first surface than the second surface;
forming a first insulating layer in the first cavity, the first insulating layer being spaced from the first surface by the first plurality of conductive layers;
forming a second plurality of conductive layers in the first cavity closer to the second surface than the first surface;
forming a second cavity in the package, the second cavity being closer to the second surface than the first surface;
coupling an integrated circuit chip on the first insulating layer;
coupling a waveguide to the integrated circuit and being at least partially in the second cavity; and
forming a plurality of electric connectors extending from a side of the package that is different from a side of the package from which the waveguide extends.

13. The method of claim 12 comprising forming a substrate from the first plurality of conductive layers, the first insulating layer, and the second plurality of conductive layers.

14. The method of claim 13 wherein the plurality of electric connectors extends from the package into an external environment.

15. The method of claim 13 wherein the second cavity extends from the substrate to an edge of the package.
